(19) United States
(12) Patent Application Publication
(10) Pub. No.: US 2020/0389997 A1
(43) Pub. Date: Dec. 10, 2020

(54) COOLING DEVICE INCLUDING A PLURALITY OF VALVES AND OPERATION METHOD THEREOF

(71) Applicants: Inventec (Pudong) Technology Corp., Shanghai (CN); Inventec Corporation, Taipei (TW)

(72) Inventors: Kai-Yang Tung, Taipei (TW); Hung-Ju Chen, Taipei (TW)

(21) Appl. No.: 16/571,218

(22) Filed: Sep. 16, 2019

(30) Foreign Application Priority Data
Jun. 6, 2019 (CN) 201910489661.8

(51) Int. Cl. H05K 7/20

(52) U.S. Cl. CPC H05K 7/203; H05K 7/20318; H05K 7/20836; H05K 7/20381; H05K 7/208; H05K 7/20327

(57) ABSTRACT

A cooling device includes a sink, a dielectric liquid disposed in the sink, a heat exchanger, a first tube, a second tube, a gas storage unit, a first valve, a second valve and a third valve. A first interface of the first tube is connected to a first sink interface of the sink. A second interface of the first tube is connected to a first heat exchanger interface of the heat exchanger. The second tube is connected between a second sink interface of the sink and a second heat exchanger interface of the heat exchanger. The first valve is disposed on a third interface of the first tube. The second valve is disposed between the first valve and a first gas storage unit interface of the gas storage unit. The third valve is disposed between a second gas storage unit interface of the gas storage unit and an external space.

### BACKGROUND OF THE INVENTION

### 1. Field of the Invention

The disclosure is related to a cooling device and a method for operating the cooling device, and more particularly, a cooling device including a plurality of valves and a method for operating the cooling device.

### 2. Description of the Prior Art

A two-phase immersion cooling device can be used to cool an electronic element that is prone to dissipate heat. For example, an electronic element that is prone to dissipate heat (e.g., a server) can be immersed in a dielectric liquid in a sink. When the electronic device dissipates heat, the dielectric liquid can vaporize to be a dielectric vapor, and the dielectric vapor can be condensed to become the dielectric liquid and return to the sink. The thermal energy generated by the heating electronic element can be removed when the vapor is being condensed, and the effects of dissipating heat and cooling can be achieved.

Although the above solution is feasible in the industry, some problems have been found previously. For example, in order to maintain or check the electronic element immersed in the dielectric liquid, a lid of the sink has to be opened regularly or irregularly to maintain the electronic element. Opening the lid will draw external air to the interior of the sink, increasing the internal pressure of the sink. Because it is difficult to estimate how many times the lid is opened for maintenance, it is also difficult to estimate the amount of air entering the cooling device from the ambient environment. It is not appropriate to increase the volume of the cooling device to control the internal pressure of the cooling device. In addition, the external air entering the cooling device will cause a problem of that it will be difficult to remove the external air since the external air cannot be easily separated from the dielectric vapor.

### SUMMARY OF THE INVENTION

An embodiment provides a cooling device including a sink, a dielectric liquid, a heat exchanger, a first tube, a second tube, a gas storage unit, a first valve, a second valve and a third valve. The sink includes a first sink interface and a second sink interface. The dielectric liquid is disposed in the sink wherein a heating element is disposed in the sink and immersed in the dielectric liquid. The heat exchanger includes a first heat exchanger interface and a second heat exchanger interface and is used to condense a dielectric vapor of the dielectric liquid. The first tube includes a first interface connected to the first sink interface, a second interface connected to the first heat exchanger interface, and a third interface. The second tube includes a first interface connected to the second sink interface and a second interface connected to the second heat exchanger interface. The gas storage unit includes a first gas storage unit interface and a second gas storage unit interface. The first valve is disposed on the third interface of the first tube. The second valve is disposed between the first gas storage unit interface and the first valve. The third valve is disposed between the second gas storage unit interface and an external space.

Another embodiment provides a method for operating a cooling device. The cooling device includes a sink, a dielectric liquid disposed in the sink, a heat exchanger, a first tube, a second tube, a gas storage unit, a first valve, a second valve and a third valve. A first interface of the first tube is connected to a first sink interface of the sink. A second interface of the first tube is connected to a first heat exchanger interface of the heat exchanger. The second tube is connected between a second sink interface of the sink and a second heat exchanger interface of the heat exchanger. The first valve is disposed on a third interface of the first tube. The second valve is disposed between the first valve and a first gas storage unit interface of the gas storage unit. The third valve is disposed between a second gas storage unit interface of the gas storage unit and an external space. The method includes opening the first valve and the second valve and closing the third valve when the cooling device is turned on; and decreasing a cooling capacity of the heat exchanger to increase an internal pressure of the cooling device.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a cooling device according to an embodiment.

FIG. 2 illustrates a method for operating the cooling device of FIG. 1 according to an embodiment.

FIG. 3 illustrates a flowchart of performing the functional operation of FIG. 2 when the functional operation is an open lid maintenance operation according to an embodiment.

FIG. 4 illustrates a flowchart of performing the functional operation of FIG. 2 when the functional operation is a turn-off operation according to another embodiment.

### DETAILED DESCRIPTION

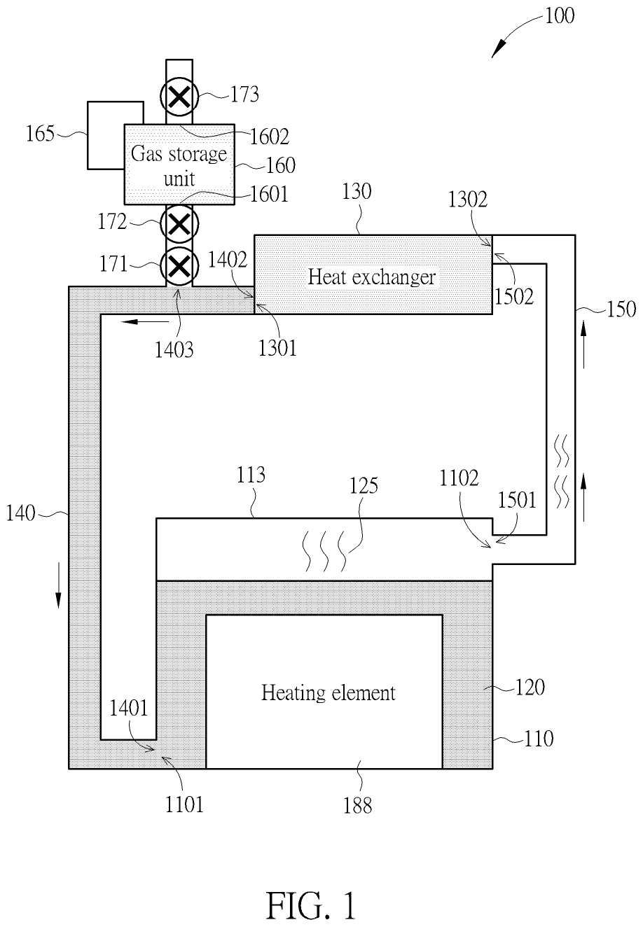

FIG. 1 illustrates a cooling device 100 according to an embodiment. The cooling device 100 includes a sink 110, a dielectric liquid 120, a heat exchanger 130, a first tube 140, a second tube 150, a gas storage unit 160, a first valve 171, a second valve 172 and a third valve 173. The sink 110 includes a first sink interface 1101 and a second sink interface 1102. The dielectric liquid 120 is disposed in the sink 110 where a heating element 188 is disposed in the sink 110 and immersed in the dielectric liquid 120. The heat exchanger 130 includes a first heat exchanger interface 1301 and a second heat exchanger interface 1302 and is used to condense a dielectric vapor 125 of the dielectric liquid 120. The first tube 140 includes a first interface 1401, a second interface 1402 and a third interface 1403 where the first interface 1401 is connected to the first sink interface 1101, and the second interface 1402 is connected to the first heat exchanger interface 1301. The second tube 150 includes a first interface 1501 and a second interface 1502 where the first interface 1501 is connected to the second sink interface 1102 and the second interface 1502 is connected to the second heat exchanger interface 1302. The gas storage unit 160 includes a first gas storage unit interface 1601 and a second gas storage unit interface 1602. The first valve 171 is disposed on the third interface 1403 of the first tube 140. The second valve 172 is disposed between the first gas storage unit interface 1601 and the first valve 171. The third valve 173 is disposed between the second gas storage unit interface 1602 and an external space. The mentioned external space may be a space outside the cooling device 100.

According to an embodiment, as shown in FIG. 1, a height of the first sink interface 1101 may be lower than a height of the second sink interface 1102. Hence, the first sink interface 1101 may be located below a liquid level of the dielectric liquid 120 and in the dielectric liquid 120, and the second sink interface 1102 may be located above the liquid level of the dielectric liquid 120. According to an embodiment, the sink 110 may further include an upper lid 113. A user may open the lid 113 to maintain the heating element 188. For example, the heating element 188 may include at least a server, a circuit board, a chip and/or another element which would dissipate heat during operation.

According to an embodiment, as shown in FIG. 1, the cooling device 100 may further include a heat exchange device 165 disposed beside the gas storage unit 160 to cool the gas storage unit 160. According to an embodiment, the heat exchange device 165 may include a fan or a condenser tube. According to an embodiment, a volume of the gas storage unit 160 may be adjustable. For example, the gas storage unit 160 may be a balloon body formed with an elastic material or a flexible unit with a bellow structure. According to an embodiment, a cooling capacity of the heat exchanger 130 may be adjustable. For example, a rotation speed of a fan disposed on the heat exchanger 130 may be adjustable, or a flow rate of a coolant in a condenser tube may be adjustable. According to an embodiment, the heat exchanger 130 may be a first heat exchanger, and the heat exchange device 165 may be a second heat exchanger.

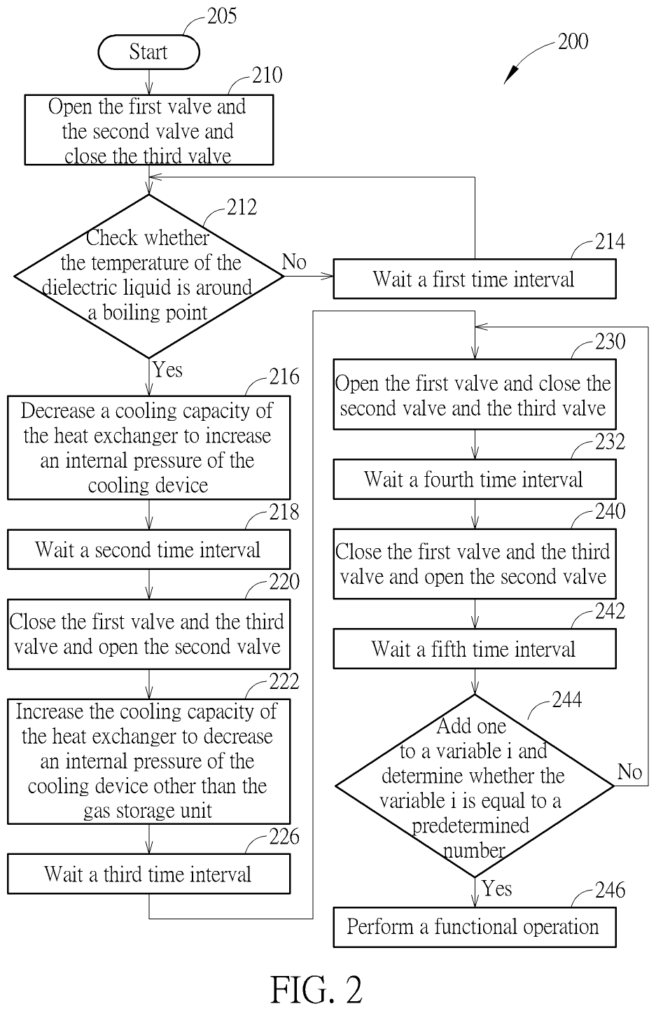

According to an embodiment, in the cooling device 100 of FIG. 1, when the heating element 188 dissipates heat, the dielectric liquid 120 may be evaporated by heat and become the dielectric vapor 125. The dielectric vapor 125 may enter the heat exchanger 130 through the second tube 150 and return to the dielectric liquid 120 through heat exchange. The dielectric liquid 120 in the heat exchanger 130 may flow back to the sink 110 through the first tube 140. For the sink 110, the first tube 140 may be an inlet tube, and the second tube 150 may be an outlet tube. As the volume of the dielectric vapor 125 and/or gas other than the dielectric vapor 125 increases, the dielectric vapor 125 and/or gas may enter the gas storage unit 160 to control an internal pressure. However, by merely using the gas storage unit 160 to control the internal pressure, it is difficult to deal with the gas entering the cooling device 100 when opening the lid 113, and it is also difficult to perform more accurate controls. Hence, according to an embodiment, a method of FIG. 2 may be performed.

FIG. 2 illustrates a method 200 for operating the cooling device 100 of FIG. 1 according to an embodiment. The method 200 may include the following steps.

Step 205: start;

Step 210: open the first valve 171 and the second valve 172 and close the third valve 173;

Step 212: check whether the temperature of the dielectric liquid 120 is around a boiling point; if so, go to Step 216; else, go to Step 214;

Step 214: wait a first time interval; go to Step 212;

Step 216: decrease a cooling capacity of the heat exchanger 130 to increase an internal pressure of the cooling device 100;

Step 218: wait a second time interval;

Step 220: close the first valve 171 and the third valve 173 and open the second valve 172;

Step 222: increase the cooling capacity of the heat exchanger 130 to decrease an internal pressure of the cooling device 100 other than the gas storage unit 160;

Step 226: wait a third time interval;

Step 230: open the first valve 171 and close the second valve 172 and the third valve 173;

Step 232: wait a fourth time interval;

Step 240: close the first valve 171 and the third valve 173 and open the second valve 172;

Step 242: wait a fifth time interval;

Step 244: add one to a variable i and determine whether the variable i is equal to a predetermined number N; if so, go to Step 246; else, go to Step 230; and

Step 246: perform a functional operation.

In FIG. 2 to FIG. 4, opening a valve implies that the valve is opened if the valve is originally closed, and that the valve is kept open if the valve is originally opened. Likewise, closing a valve implies the valve is closed if the valve is originally opened, and the valve is kept closed if the valve is originally closed.

In Step 216, for example, a fan speed of the heat exchanger 130 may be decreased or a cooling capacity of a condenser tube of the heat exchanger 130 may be decreased, so the cooling device 100 may slightly overheat. In the cooling device 100, the dielectric vapor 125 may increase, volumes of the dielectric vapor 120 and a gas other than the dielectric vapor 120 may increase, and the internal pressure may therefore increase. In Step 218, a mixed gas (including the dielectric vapor 125 and the gas other than the dielectric vapor 125) may enter the gas storage unit 160 more easily.

In Step 222, for example, a fan speed of the heat exchanger 130 may be adjusted to an original level or a cooling capacity of a condenser tube of the heat exchanger 130 may be adjusted to an original level. Step 222 may be activated according to a sensing result of a temperature sensor disposed on the cooling device 100. That is to say, the heat exchanger 130 may be controlled to perform Step 222 when the temperature sensor senses that the temperature reaches a threshold. In Step 226, it may be waited for that the dielectric vapor 125 to condense. In Step 220 to Step 226, the gas storage unit 160 may be isolated from the part of the cooling device 100 other than the gas storage unit 160. During these steps, in the part of the cooling device 100 other than the gas storage unit 160, the ratio of the gas other than the dielectric vapor 125 may be low, and the internal pressure is also low. Hence, the performance of the heat exchanger 130 may be improved, and the dissipation of the dielectric vapor 125 may be reduced.

As shown in FIG. 2, Step 230 to Step 240 may be performed repeatedly. The variable i in Step 244 may be an integer, and 0≤i≤N. For example, if an initial value of i is zero, and N is 5, Step 230 to Step 244 may be performed repeatedly for five times. In another example, if an initial value of i is zero, and N is 7, Step 230 to Step 244 may be performed repeatedly for seven times. Likewise, when i and N are other integers, the number of times of performing Step 230 to Step 244 may be obtained according to i and N in this way.

In Step 232, it may be waited for the condensed dielectric liquid 120 between the first valve 171 and the second valve 172 to drop or flow back to the first tube 140. In Step 242, it may be waited for the dielectric vapor 125 in the gas storage unit 160 to condense to become the dielectric liquid 120 and enter a space between the first valve 171 and the second valve 172. By performing Step 230 to Step 242 repeatedly, the dielectric liquid 120 entering the gas storage unit 160 may be recycled back to the sink 110. In Step 230 to Step 242, the heat exchange device 165 may be optionally used to cool the dielectric vapor 125 in the gas storage unit 160 to condense the dielectric vapor 125 into the dielectric liquid 120 and reduce the volume of the gas storage unit 160.

According to an embodiment, when the internal pressure in the gas storage unit 160 is higher than the internal pressure of the portion of cooling device 100 other than the gas storage unit 160, the dielectric liquid 120 may be better drawn back to the first tube 140 from the gas storage unit 160. The dielectric liquid 120 may further return to a circulating path of the sink 110, the second tube 150, the heat exchanger 130 and the first tube 140.

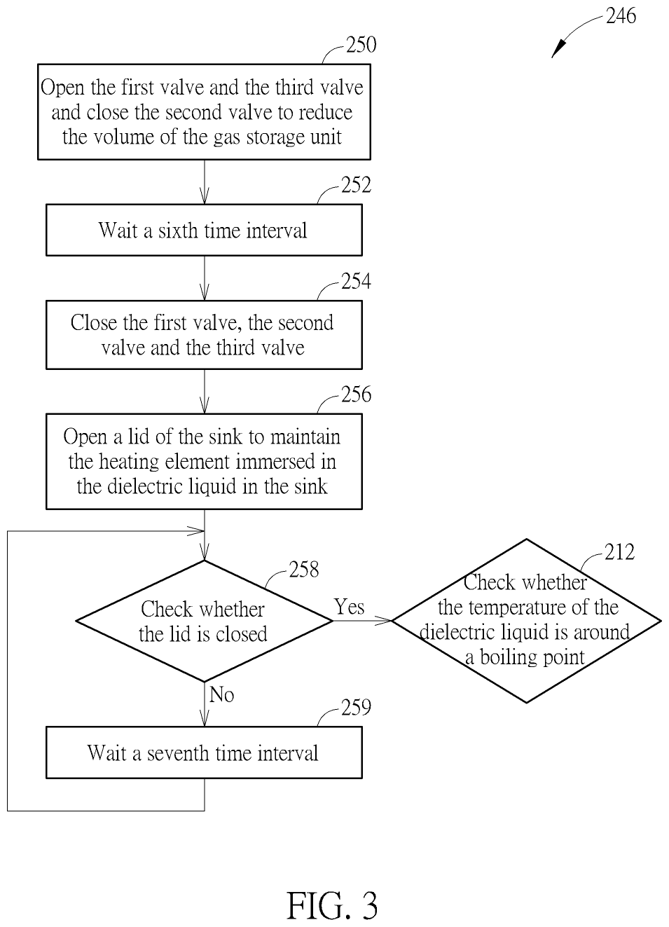

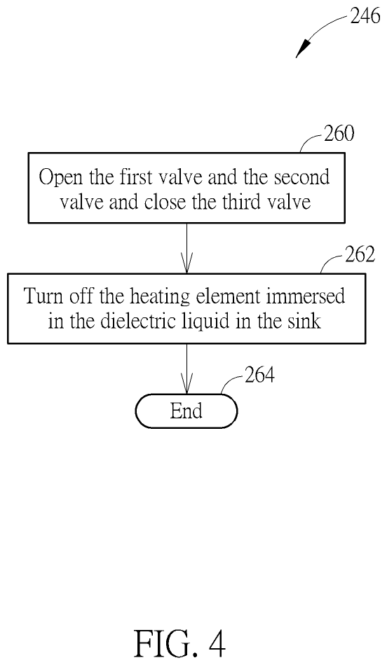

According to an embodiment, the functional operation of Step 246 may be a turn-off operation or an open lid maintenance operation. FIG. 3 illustrates a flowchart of Step 246 when the functional operation of Step 246 is an open lid maintenance operation according to an embodiment. FIG. 4 illustrates a flowchart of Step 246 when the functional operation of Step 246 is a turn-off operation according to an embodiment.

When the functional operation of Step 246 is an open lid maintenance operation, as shown in FIG. 3, Step 246 may include following steps.

Step 250: open the first valve 171 and the third valve 173 and close the second valve 172 to reduce the volume of the gas storage unit 160;

Step 252: wait a sixth time interval;

Step 254: close the first valve 171, the second valve 172 and the third valve 173;

Step 256: open a lid 113 of the sink 110 to maintain the heating element 188 immersed in the dielectric liquid 120 in the sink 110;

Step 258: check whether the lid 113 is closed; if so, enter Step 212; else, enter Step 259; and

Step 259: wait a seventh time interval; enter Step 258.

In Step 250 to Step 252 of FIG. 3, because the third valve 173 is opened, a mixed gas (including the dielectric vapor 125 and the gas other than the dielectric vapor 125) in the gas storage unit 160 may be removed, and the volume of the gas storage unit 160 may be reduced. Hence, the gas storage unit 160 may be able to contain the air entering the cooling device 100 during the open lid maintenance operation. Because the first valve 171 is opened and the second valve 172 is closed, the dielectric liquid 120 between the first valve 171 and the second valve 172 may be drawn back into the first tube 140. In Step 254, by closing the first valve 171, the second valve 172 and the third valve 173, the dissipation of the dielectric vapor 125 may be better prevented. In Step 256, according to an embodiment, a notice such as “it is ok to open the lid now” may be shown on a display to inform a user when the lid is allowed to be opened. By means of the flows of FIG. 2 and FIG. 3, the problem of the air entering the cooling device 100 caused by the open lid maintenance operation may be resolved.

When the functional operation of Step 246 is a turn-off operation, as shown in FIG. 4, Step 246 may include following steps.

Step 260: open the first valve 171 and the second valve 172 and close the third valve 173;

Step 262: turn off the heating element 188 immersed in the dielectric liquid 120 in the sink 110;

Step 264: end.

In Step 260, the mixed gas in the gas storage unit 160 may get back to the first tube 140 to reduce the dissipation of the dielectric liquid 120. In Step 262, turning off the heating element 188 may be an operation such as turning off a server.

In summary, by means of a cooling device including a plurality of valves and a method for operating the cooling device, the problem caused by an open lid maintenance operation of a two-phase immersion cooling device may be effectively dealt with, and the dissipation of the dielectric vapor may be reduced.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A cooling device comprising:
a sink comprising a first sink interface and a second sink interface;
a dielectric liquid disposed in the sink wherein a heating element is disposed in the sink and immersed in the dielectric liquid;
a first heat exchanger comprising a first heat exchanger interface and a second heat exchanger interface and configured to condense a dielectric vapor of the dielectric liquid;
a first tube comprising a first interface connected to the first sink interface, a second interface connected to the first heat exchanger interface, and a third interface;
a second tube comprising a first interface connected to the second sink interface and a second interface connected to the second heat exchanger interface;
a gas storage unit comprising a first gas storage unit interface and a second gas storage unit interface;
a first valve disposed on the third interface of the first tube;
a second valve disposed between the first gas storage unit interface and the first valve; and
a third valve disposed between the second gas storage unit interface and an external space.

2. The cooling device of claim 1, wherein the first valve and the second valve are opened and the third valve is closed when the cooling device is turned on.

3. The cooling device of claim 1, wherein the first valve and the third valve are closed and the second valve is opened after a mixed gas enters the gas storage unit.

4. The cooling device of claim 1, further comprising a second heat exchanger configured to cool the gas storage unit.

5. The cooling device of claim 1, wherein the first valve is opened and the second valve and the third valve are closed after the dielectric vapor is condensed.

6. A method for operating a cooling device, the cooling device comprising a sink, a dielectric liquid disposed in the sink, a heat exchanger, a first tube, a second tube, a gas storage unit, a first valve, a second valve and a third valve, a first interface of the first tube being connected to a first sink interface of the sink, a second interface of the first tube being connected to a first heat exchanger interface of the heat exchanger, the second tube being connected between a second sink interface of the sink and a second heat exchanger interface of the heat exchanger, the first valve being disposed on a third interface of the first tube, the second valve being disposed between the first valve and a first gas storage unit interface of the gas storage unit, the third valve being disposed between a second gas storage unit interface of the gas storage unit and an external space, the method comprising:
opening the first valve and the second valve and closing the third valve when the cooling device is turned on; and
decreasing a cooling capacity of the heat exchanger to increase an internal pressure of the cooling device.

7. The method for operating the cooling device of claim 6 further comprising:
closing the first valve and the third valve and opening the second valve after a mixed gas enters the gas storage unit; and
increasing the cooling capacity of the heat exchanger to decrease an internal pressure of the cooling device other than the gas storage unit.

8. The method for operating the cooling device of claim 7 further comprising:
opening the first valve and closing the second valve and the third valve after a dielectric vapor of the dielectric liquid is condensed; and
closing the first valve and the third valve and opening the second valve.

9. The method for operating the cooling device of claim 8 further comprising:
opening the first valve and the third valve and closing the second valve to reduce a volume of the gas storage unit when performing an open lid maintenance operation;
closing the first valve, the second valve and the third valve; and
opening a lid of the sink to maintain a heating element immersed in the dielectric liquid in the sink.

10. The method for operating the cooling device of claim 8 further comprising:
opening the first valve and the second valve and closing the third valve when performing a shutdown operation; and
turning off a heating element immersed in the dielectric liquid in the sink.
